(19) United States
(12) Patent Application Publication
(10) Pub. No.: US 2014/0287563 A1
(43) Pub. Date: Sep. 25, 2014

(54) METHOD OF MANUFACTURING SEMICONDUCTOR DEVICE

(71) Applicant: KABUSHIKI KAISHA TOSHIBA, Minato-ku (JP)

(72) Inventors: Akira Komatsu, Kanagawa-ken (JP); Kaori Fuse, Kanagawa-ken (JP)

(73) Assignee: KABUSHIKI KAISHA TOSHIBA, Minato-ku (JP)

(21) Appl. No.: 14/019,223

(22) Filed: Sep. 5, 2013

(30) Foreign Application Priority Data
Mar. 22, 2013 (JP) 2013-061111

(51) Int. Cl. H01L 29/66; H01L 21/28; H01L 21/266

(52) U.S. Cl. CPC H01L 29/66666; H01L 21/266; H01L 21/28008
USPC 438/270

(57) ABSTRACT

An aspect of the present embodiment, there is provided a method of manufacturing a semiconductor device, including adsorbing a photolytic group on a hydrophilic surface of a substrate on which a concave portion is provided, irradiating a first area of the substrate with light to transform the photolytic group to a hydrophobic group to modify a surface of the first area, selectively coating a resist on a second area which is a portion of the substrate other than the first area modified by hydrophobic group.

### CROSS REFERENCE TO RELATED APPLICATION

This application is based upon and claims the benefit of priority from prior Japanese Patent Application No. 2013-061111, filed on Mar. 22, 2013, the entire contents of which are incorporated herein by reference.

### FIELD

Exemplary embodiments described herein generally relate to a method of manufacturing a semiconductor device.

### BACKGROUND

Miniaturization of a semiconductor device may cause to decrease productivity or reliability. A trench gate structure may be used for a power semiconductor device, for example.

In the semiconductor device including the trench gate structure, miniaturization of the trench gate structure is necessary to decrease on-resistance while retaining higher break down voltage.

However, when an aspect ratio of the trench gate is increased due to the miniaturization, productivity or reliability may be decreased.

### BRIEF DESCRIPTION OF THE DRAWINGS

FIGS. 1A-1E are schematically cross-sectional views showing a method of manufacturing a semiconductor device according to an embodiment;

FIGS. 2A-2C are schematically cross-sectional views showing processing steps of manufacturing the semiconductor device according to the embodiment;

FIGS. 3A-3B are schematically cross-sectional views showing the processing steps following FIG. 2 of manufacturing the semiconductor device according to the embodiment;

FIGS. 4A-4C are schematically cross-sectional views showing the processing steps following FIG. 3 of manufacturing the semiconductor device according to the embodiment;

FIGS. 5A-5C are schematically cross-sectional views showing processing steps of manufacturing a semiconductor device according to a comparative case;

FIGS. 6A-6B are schematically cross-sectional views showing the processing steps following FIG. 5 of manufacturing the semiconductor device according to the comparative case.

### DETAILED DESCRIPTION

An aspect of the present embodiment, there is provided a method of manufacturing a semiconductor device, including adsorbing a photolytic group on a hydrophilic surface of a substrate on which a concave portion is provided, irradiating a first area of the substrate with light to transform the photolytic group to a hydrophobic group to modify a surface of the first area, selectively coating a resist on a second area which is a portion of the substrate other than the first area modified by hydrophobic group.

Embodiments will be described below in detail with reference to the attached drawings mentioned above. Throughout the attached drawings, similar or same reference numerals show similar, equivalent or same components, and the description is not repeated. As drawings are schematic and conceptual, a relation between a thickness and a length of each portion or a ratio between portions is not necessary to identify with the corresponding real value. Further, it is not restricted to represent same size or ratio in a case of pointing out the same portion in the drawings, accordingly, the same size or ratio is differently represented in the drawings.

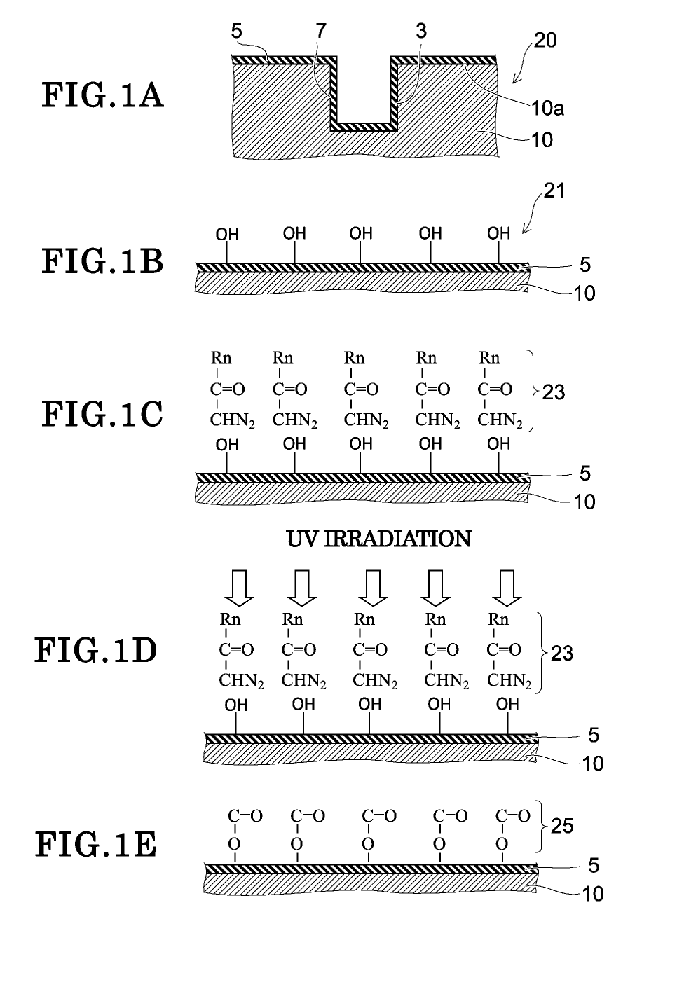

FIGS. 1A-1E are schematically cross-sectional views showing a method of manufacturing a semiconductor device according to an embodiment. As shown in FIG. 1A, a method of manufacturing a semiconductor device according to the embodiment has an advantage to a substrate having a hydrophilic surface, for example, a substrate 10 including a concave portion 7 on a surface. The concave portion 7 is a trench, a recess, a contact hole or the like provided on the surface of the substrate 10, for example. The substrate used in the embodiment is a semiconductor substrate or an epitaxial substrate on which a semiconductor film is epitaxially grown on a substrate.

As shown in FIG. 1B, a silicon oxide film 5 is provided on the surface of the substrate 10 so that the surface of the substrate 10 is modified by hydroxyl group 21 to be hydrophilicity.

As shown in FIG. 1C, a photolytic group is adsorbed on a first area of the surface of the substrate 10 provided the concave portion 7 in this embodiment. A silicon oxide film is provided on an upper surface 10a of the substrate, so that the surface has hydrophilicity. A photolytic group is composed of long-chain diazo ketone compound 23 which includes a long-chain diazo alkyl group Rn, for example.

As shown in FIG. 1D, light, ultra violet (UV) light, for example is irradiated on the first area of the substrate 10, so that the photolytic group is transformed to a hydrophobic group. In other words, a long-chain diazo ketone compound 23 is decomposed by light to react with a hydroxyl group 21. In such a manner, a surface of the first area can be modified by a carbonyl group 25 with hydrophobicity as shown in FIG. 1E.

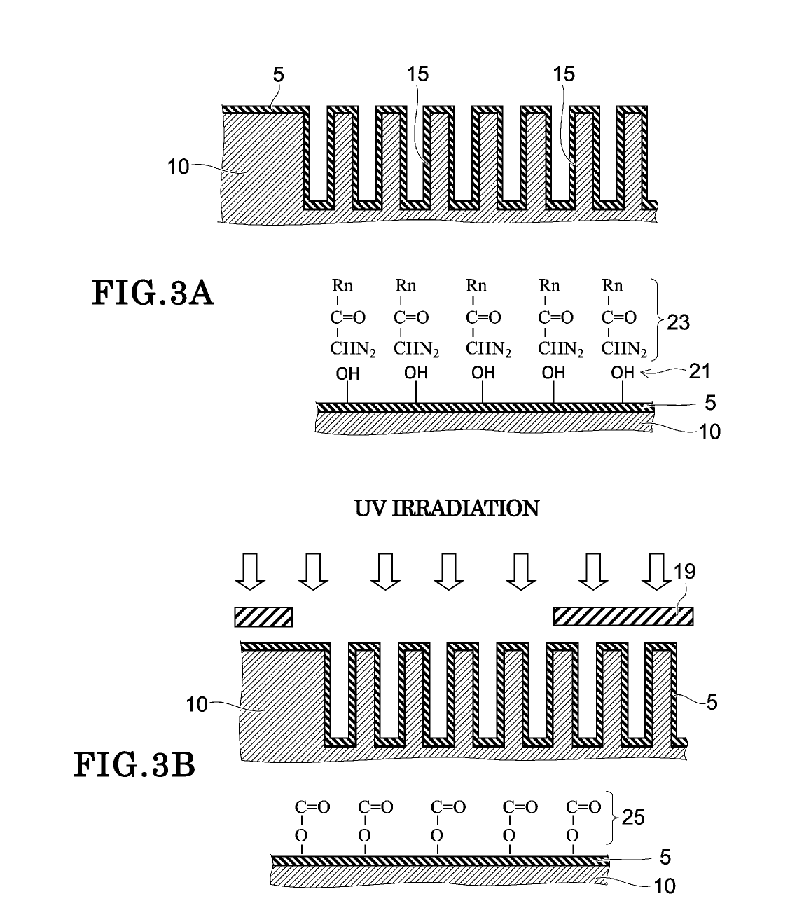

On the other hand, a second area other than the first area in the substrate 10 is not irradiated by light as shown in FIG. 3B. Therefore, hydrophilicity in a surface of the second area is retained. As a result, a resist can be selectively coated on the second area other than the first area in the substrate 10.

In such a manner, a portion of the surface of the substrate is transformed by photo-induced hydrophobizing reaction to have high hydrophobicity in the method of manufacturing the semiconductor device in this embodiment. In such a manner, a portion where the resist is not selectively coated can be formed, when the resist is coated on the surface of the substrate.

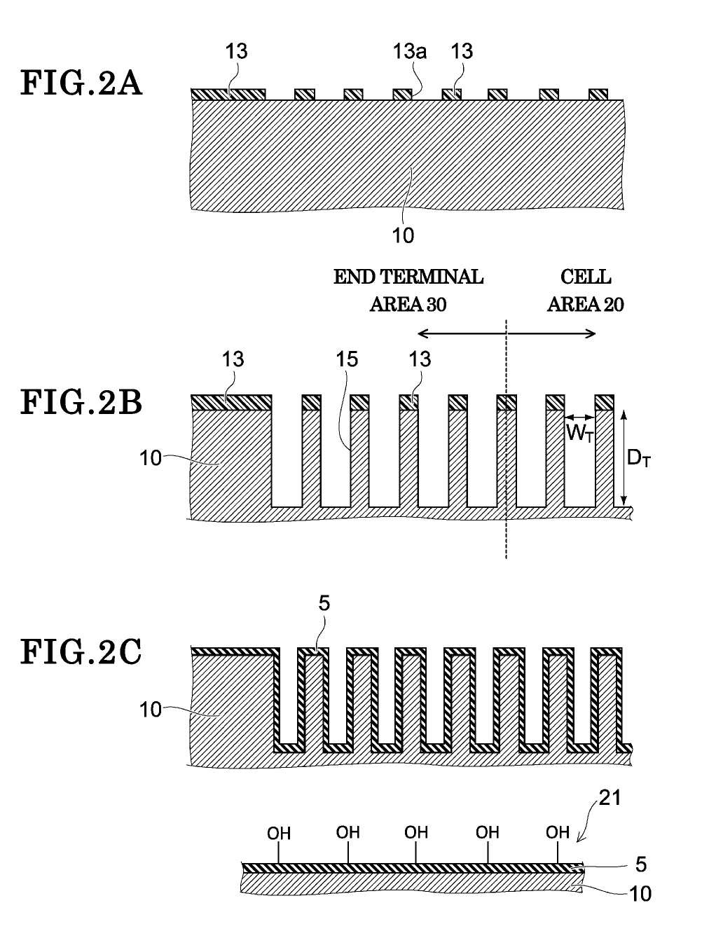

Next, processing steps of the semiconductor device is described as reference to FIGS. 2A-4C, which are schematically cross-sectional views showing the processing steps of manufacturing the semiconductor device according to the embodiment.

As shown in FIG. 2A, a resist mask 13 is formed on a substrate 10. The resist mask 13 has a plurality of openings 13a. The substrate 10 is an epitaxial layer provided on a semiconductor substrate. The substrate 10 may be the semiconductor substrate. The substrate 10 has a silicon layer which is epitaxially grown on a silicon wafer.

As shown in FIG. 2B, the substrate is selectively etched using the resist mask 13 to form a plurality of trenches 15. Each of the trenches 15 are provided both a cell unit 20 and an end terminal unit 30. The end terminal unit 30 is a first area, for example, a second cell unit 20 is a second area.

The trench 15 is formed by reactive ion etching (RIE), for example. A depth DT and a width WT of the trench 15 are set to be 5-10 μm and 1-2 μm, for example, respectively.

As shown in FIG. 2C, a silicon oxide film 5, for example, is formed on a surface of a substrate 10. The silicon oxide film 5 is formed by thermally oxidizing the substrate 10 (silicon layer), for example. The silicon oxide film 5 is formed on the cell unit 20 and the end terminal unit 30. Further, the surface of the silicon oxide film 5 is modified by hydroxyl group 21 to be hydrophilicity.

As shown in FIG. 3A, a long-chain diazo ketone compound 23 is dissolved in an organic solvent, for example, so that the solution is coated on the substrate 10. In such a manner, the long-chain diazo ketone compound 23 is chemically adsorbed to the hydroxyl group 21 which modifies the silicon oxide film 5 as shown in FIG. 3A.

As shown in FIG. 3B, UV Light is irradiated on an end terminal unit 30 using a photo mask 19. In such a manner, the long-chain diazo ketone compound 23 is decomposed to react with hydroxyl group 21. Accordingly, the surface of the silicon oxide film 5 in the end terminal unit 30 can be modified by a carbonyl group 25 in a hydrophobic group. In other words, the surface of the end terminal unit 30 is transformed to hydrophobicity.

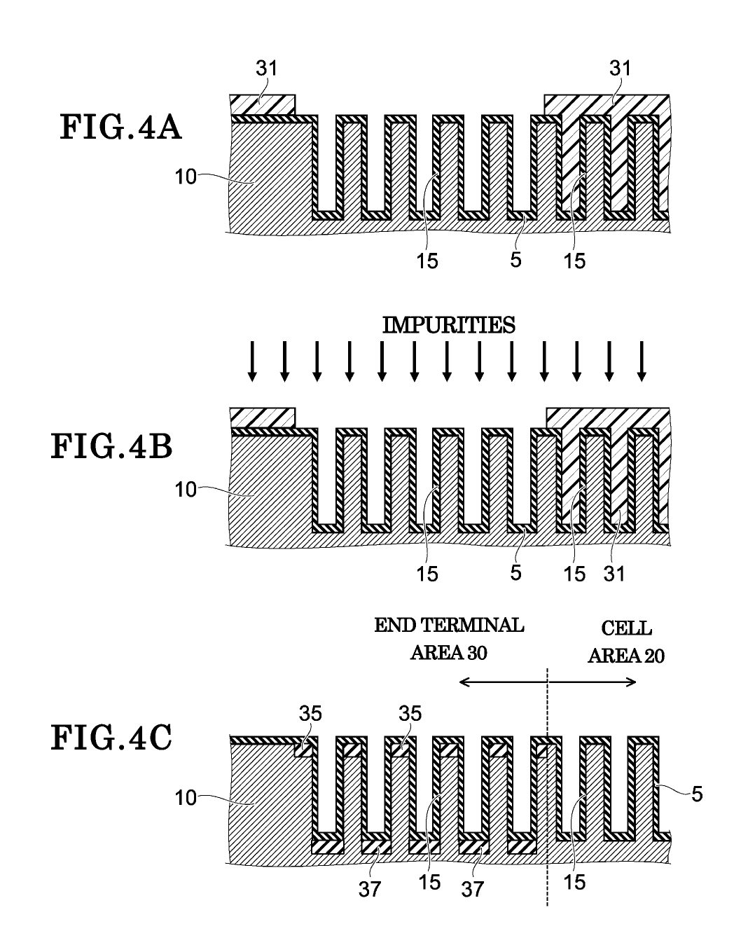

As shown in FIG. 4A, a resist 31 is coated on the substrate 10. The resist 31 is entirely coated on the surface of the substrate 10 by a spin-coater. However, the surface of the end terminal unit 30 is modified by carbonyl group 25 to be hydrophobicity. As a result, the resist 31 is not coated on the end terminal unit 30 and is selectively coated on an area of the cell unit 20 and outside of and the end terminal unit 30, other than the end terminal unit 30.

As shown in FIG. 4B, ion implantation is carried out onto the substrate 10 using the resist 31 as a mask. In such a manner, impurities can be introduced in an upper surface of the substrate 10 and a bottom surface of the trench 15 in the end terminal unit 30.

As shown in FIG. 4C, heat treatment is carried out to activate the impurities in the substrate 10. In such a manner, an impurity-doped layer 35 on the substrate 10 and impurity-doped layer 37 beneath the bottom surface of the trench 15 can be formed.

The processing steps described above are a part of a fabricating process of MOS transistors and demonstrate a process of forming the end terminal unit 30. The end terminal unit 30 is provided in a periphery region around the cell unit 20 in which a base layer, emitter layer, and trench gate, for example, are provided.

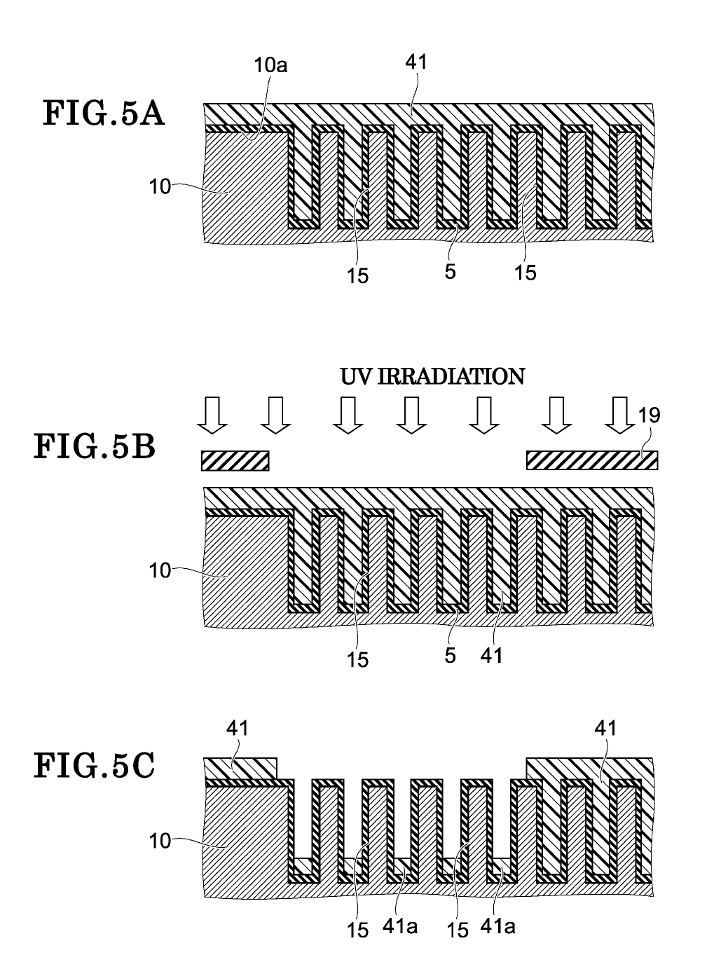

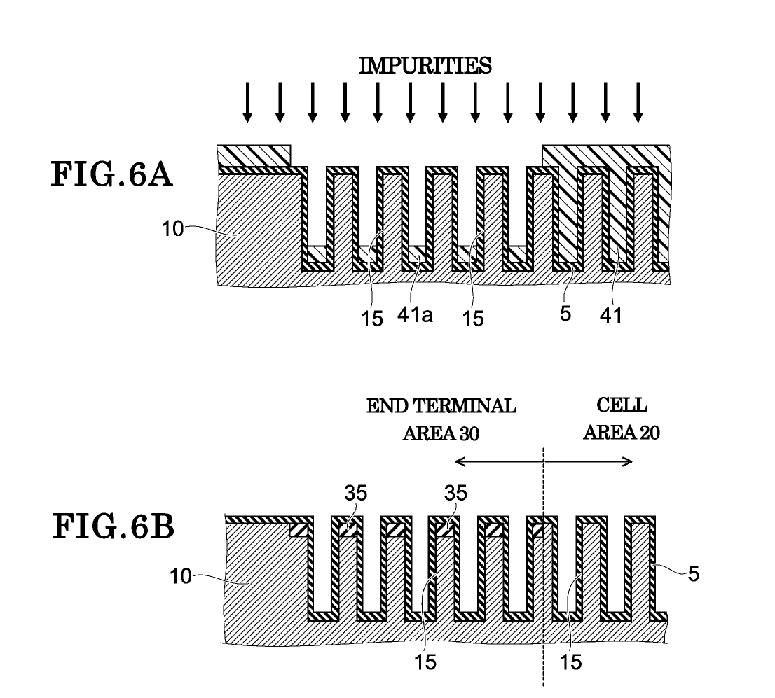

Next, processing steps of a semiconductor device is described as reference to FIGS. 5A-6B, which are schematically cross-sectional views showing the processing steps of manufacturing the semiconductor device according to a comparative case.

As shown in FIG. 5A, a photo resist 41 is coated on the substrate 10 in which the trenches 15 and the silicon oxide film 5 are provided. The photo resist 41 is a positive type, for example, and is coated on the upper surface 10a of the substrate 10. The photo resist 41 is coated to be embedded in the trenches.

As shown in FIG. 5B, UV light is selectively irradiated using the photo mask 19, for example, to expose the photo resist 41 coated on the end terminal unit 30.

As shown in FIG. 5C, the photo resist 41 is developed to remove a portion on which UV light is irradiated. In such the process, a portion 41 of the resist 41 coated in the bottom of each of the trenches 15 may be leaved. In other words, the resist embedded in the bottom of the trench 15 may not be sufficiently exposed to be leaved in the bottom of the trench 15. In a case the depth DT of the trench 15 being over 5 μm and the width WT of the trench 15 being narrower, for example, UV light may be not penetrated into the bottom to easily produce residue of the resist 41.

As shown in FIG. 6A, when ion implantation is performed in a state that the portion of the resist 41 is leaved in the bottom of the trench 15, the impurities in not introduced in the bottom of the trench 15. Accordingly, as shown in FIG. 6B, the impurity-doped layer 35 is formed on the substrate 10, however, the impurity-doped layer 37 is not formed beneath the bottom surface of the trench 15. As a result, desired end terminal structure is not constituted, and breakdown voltage of the end terminal unit 30 may be lowered, for example.

On the contrary, the end terminal unit 30 is transformed by photo-exited hydrophobizing reaction to be hydrophobicity in this embodiment, such that the resist cannot be coated on the end terminal unit 30. Accordingly, the resist is not leaved in the bottom of the trench 15, and the desired end terminal structure can be precisely formed. In such a manner, product yield and reliability of the semiconductor devices can be improved.

A processing step of developing the resist can be omitted in this embodiment to simplify the fabricating process. Furthermore, the resist used in this embodiment is not necessary to be photo-sensitive. Accordingly, a selection area of the material can be widened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
adsorbing a photolytic group on a hydrophilic surface of a substrate on which a concave portion is provided;
irradiating a first area of the substrate with light to transform the photolytic group to a hydrophobic group to modify a surface of the first area;
selectively coating a resist on a second area which is a portion of the substrate other than the first area modified by hydrophobic group.

2. The method of claim 1, wherein
the photolytic group is a long-chain diazo ketone compound and the hydrophobic group is a carbonylic group.

3. The method of claim 1, further comprising:
providing a silicon oxide film on the substrate, before adsorbing the photolytic group on the hydrophilic surface of the substrate.

4. The method of claim 1, further comprising:
ion-implanting impurities into the substrate using the resist as a mask, after selectively coating the resist.

5. The method of claim 1, wherein
the first area is an end terminal area which surrounds the second area.

6. The method of claim 1, wherein
the second area is a cell area.

7. The method of claim 6, wherein
the cell area includes a base layer, an emitter layer and a trench gate.

8. The method of claim 1, wherein
the concave portion includes at least one selected from a trench, recess and a contact hole.

9. The method of claim 1, wherein
the concave portion is formed by reactive ion etching.

10. The method of claim 1, wherein
the concave portion is the trench and an impurity layer is provided beneath a bottom surface of the trench by ion-implanting.

11. The method of claim 10, wherein
a depth and a width of the trench are 5-10 μm and 1-2 μm, respectively.

12. The method of claim 1, wherein
the substrate is a silicon substrate or a silicon substrate on which a film is epitaxially grown.
